(19) United States
(12) Patent Application Publication
(10) Pub. No.: US 2026/0090118 A1
(43) Pub. Date: Mar. 26, 2026

(54) SOLID-STATE IMAGING DEVICE

(71) Applicants: Kabushiki Kaisha Toshiba, Tokyo (JP); Toshiba Electronic Devices & Storage Corporation, Tokyo (JP)

(72) Inventor: Minoru KASHIWAGI, Chigasaki Kanagawa (JP)

(21) Appl. No.: 19/054,397

(22) Filed: Feb. 14, 2025

(30) Foreign Application Priority Data
Sep. 24, 2024 (JP) 2024-165345

(51) Int. Cl. H10F 39/00

(52) U.S. Cl. CPC H10F 39/8063; H10F 39/8053; H10F 39/811

(57) ABSTRACT

According to one embodiment, a solid-state imaging device includes: a plurality of pixels provided on a substrate and arranged in a first direction and a second direction that are parallel to a surface of the substrate and intersect with each other; and a plurality of microlenses provided above the substrate, wherein each of the plurality of microlenses has a semi-cylindrical or semi-elliptic cylindrical structure extending in the first direction.

### CROSS-REFERENCE TO RELATED APPLICATIONS

This application is based upon and claims the benefit of priority from prior Japanese Patent Application No. 2024-165345, filed Sep. 24, 2024, the entire contents of which are incorporated herein by reference.

### FIELD

Embodiments described herein relate generally to a solid-state imaging device.

### BACKGROUND

In a solid-state imaging device, a microlens may be used to prevent a decrease in sensitivity of a pixel.

### BRIEF DESCRIPTION OF DRAWINGS

FIG. 1 is a block diagram illustrating the configuration example of a solid-state imaging device according to a first embodiment.

FIG. 2 is a bird's eye view illustrating the structure example of the solid-state imaging device according to the first embodiment.

FIG. 3 is a plan view illustrating the structure example of the solid-state imaging device according to the first embodiment.

FIG. 4 is a cross-sectional view illustrating the structure example of the solid-state imaging device according to the first embodiment.

FIG. 5 is a cross-sectional view illustrating the structure example of the solid-state imaging device according to the first embodiment.

FIG. 6 is a plan view illustrating the structure example of a solid-state imaging device according to a second embodiment.

FIG. 7 is a cross-sectional view illustrating the structure example of the solid-state imaging device according to the second embodiment.

FIG. 8 is a plan view illustrating the structure example of a solid-state imaging device according to a third embodiment.

FIG. 9 is a cross-sectional view illustrating the structure example of the solid-state imaging device according to the third embodiment.

FIG. 10 is a cross-sectional view illustrating the structure example of the solid-state imaging device according to the third embodiment.

### DETAILED DESCRIPTION

### Embodiments

In general, according to one embodiment, a solid-state imaging device includes: a plurality of pixels provided on a substrate and arranged in a first direction and a second direction that are parallel to a surface of the substrate and intersect with each other; and a plurality of microlenses provided above the substrate, wherein each of the plurality of microlenses has a semi-cylindrical or semi-elliptic cylindrical structure extending in the first direction.

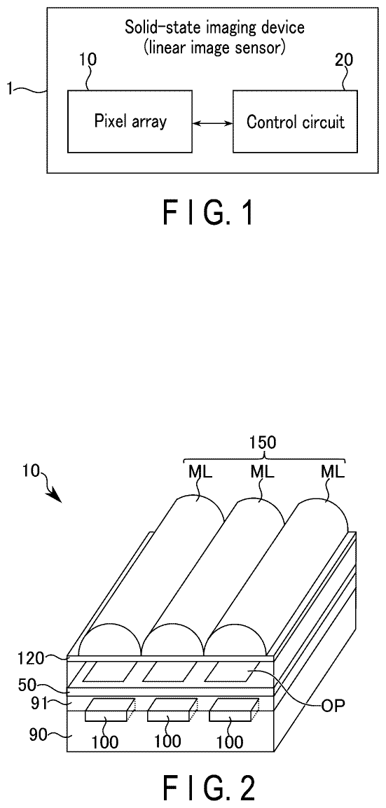

Solid-state imaging devices according to embodiments will be described with reference to FIGS. 1 to 10. In the following description, elements having the same function and configuration are denoted by the same reference numerals. In each of the following embodiments, in a case where components (for example, circuits, interconnects, various voltages and signals, and the like) with reference numeral with numeric character/alphabetical letter at the end for distinguishing are not necessarily distinguished from each other, a description (reference numeral) in which the numeric character/alphabetical letter at the end is omitted is used.

### (1) First Embodiment

A solid-state imaging device according to a first embodiment will be described with reference to FIGS. 1 to 5.

### Configuration Example

FIG. 1 is a block diagram illustrating the configuration example of a solid-state imaging device according to the present embodiment.

A solid-state imaging device 1 according to the present embodiment includes a pixel array 10 and a control circuit 20.

The pixel array 10 receives light from a subject. The pixel array 10 converts the received light into an electrical signal.

The control circuit 20 controls the operation of the pixel array 10. The control circuit 20 controls a light sampling timing in the pixel array 10. The control circuit 20 performs various types of signal processings on the electrical signal acquired by the pixel array 10.

The solid-state imaging device 1 according to the present embodiment illustrated in FIG. 1 is, for example, a linear image sensor. The linear image sensor includes, for example, a frontside-illuminated CMOS image sensor or a frontside-illuminated CCD image sensor.

FIG. 2 is a bird's-eye view illustrating the structure example of the pixel array 10 in the solid-state imaging device 1 according to the present embodiment.

As illustrated in FIG. 2, the pixel array 10 includes a semiconductor substrate 90, an insulating layer 91, a plurality of pixels 100, an interconnect 50, a color filter 120, and a microlens array 150.

The pixels 100 are provided in the semiconductor substrate 90. The pixels 100 are arranged in an array in a plane parallel to the surface of the semiconductor substrate 90.

The insulating layer 91 is provided on the semiconductor substrate 90. The insulating layer 91 covers the surface of the semiconductor substrate 90.

The interconnect 50 is provided in the insulating layer 91. The interconnect 50 has a plurality of openings OP. The opening OP overlaps the pixel 100 in a direction perpendicular to the surface of the semiconductor substrate 90.

The color filter 120 is provided above the semiconductor substrate 90 with the insulating layer 91 interposed therebetween.

The microlens array 150 is provided above the pixels 100 with the insulating layer 91 and the color filter 120 interposed therebetween. The microlens array 150 includes a plurality of microlenses ML.

In the present embodiment, the microlens ML has a semi-cylindrical or semi-elliptic cylindrical structure. The microlenses ML extend along the arrangement direction of the pixels 100. The longitudinal direction of the microlenses ML (the axial direction of the semi-cylinder) is along the arrangement direction of the pixels 100. In a direction in which the microlenses ML are adjacent to each other, the microlenses ML have a curved surface (surface having a curvature). In the direction in which the microlenses ML are adjacent to each other, the curved surfaces of the microlenses ML adjacent to each other face each other. The microlens ML covers an end portion (outer edge portion) of the pixel 100 in an X direction and an end portion (outer edge portion) of the pixel 100 in a Y direction.

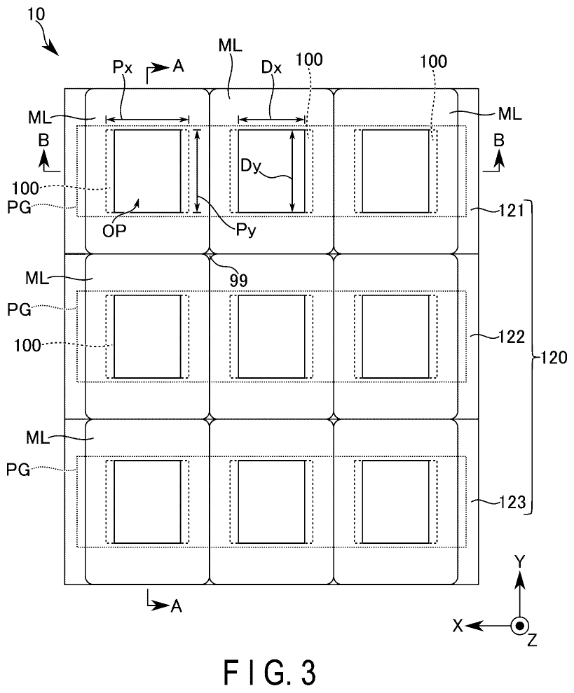

The structure of the solid-state imaging device 1 according to the present embodiment will be described more specifically with reference to FIGS. 3, 4, and 5.

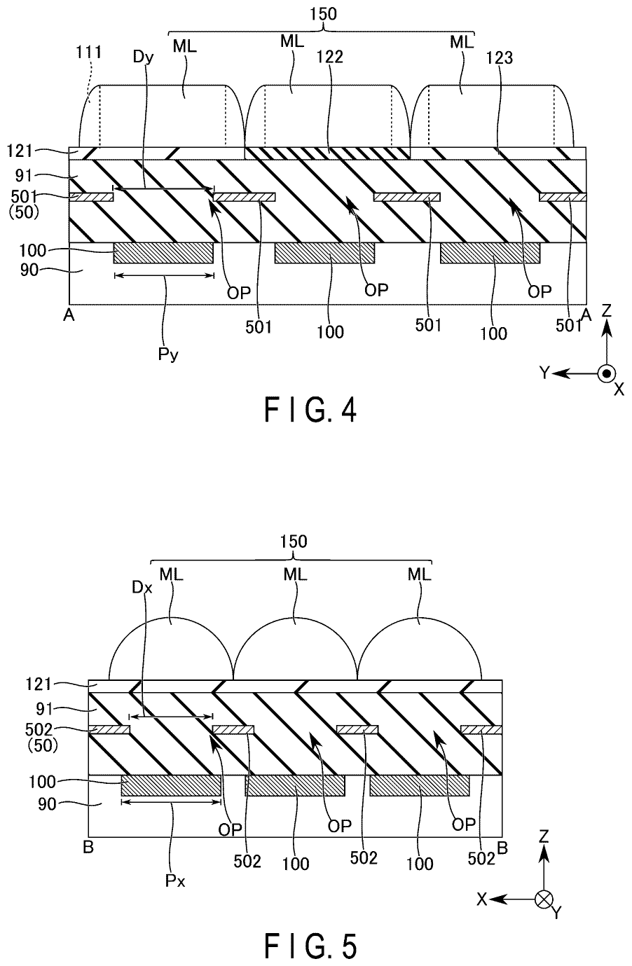

FIG. 3 is a plan view illustrating a more specific structure example of the pixel array 10 in the solid-state imaging device 1 according to the present embodiment. FIGS. 4 and 5 are cross-sectional views illustrating more specific structure examples of the pixel array 10 in the solid-state imaging device 1 according to the present embodiment. FIG. 4 illustrates the cross-sectional structure of the pixel array 10 along line A-A in FIG. 3. FIG. 5 illustrates the cross-sectional structure of the pixel array 10 along line B-B in FIG. 3.

As illustrated in FIGS. 3 to 5, the pixels 100 are arranged in the X direction (column direction of the pixel array 10) and the Y direction (row direction of the pixel array 10) parallel to the surface of the semiconductor substrate 90. A group PG of the pixels 100 arranged in the X direction forms a pixel column PG. The pixel 100 is formed of one or more semiconductor layers (diffusion layers) provided in the semiconductor substrate 90. The pixel 100 includes, for example, one or more n-type semiconductor layers and/or one or more p-type semiconductor layers. The pixel 100 includes, for example, a photodiode 100.

The dimension of the pixel (photodiode) 100 in the X direction is set as “Px”. The dimension of the pixel (photodiode) 100 in the Y direction is set as “Py”. For example, the dimension Px is equal to the dimension Py. However, the dimension Px may be different from the dimension Py depending on the specification or design of the linear image sensor.

The insulating layer 91 is provided on the surface of the semiconductor substrate 90.

The color filter 120 is provided on the insulating layer 91 in a Z direction perpendicular to the surface of the semiconductor substrate 90. The color filter 120 includes a plurality of filter layers 121, 122, 123. The filter layers 121, 122, 123 transmit light of different wavelength bands. The color filter 120 includes a red filter layer 121, a green filter layer 122, and a blue filter layer 123. Each of the filter layers 121, 122, 123 extends in the X direction. The red filter layer 121 is provided above the pixels 100 forming the pixel column PG so as to extend over the pixels 100 arranged in the X direction. The green filter layers 122 are provided above the pixels 100 forming the pixel column PG so as to extend over the pixels 100 arranged in the X direction. The blue filter layers 123 are provided above the pixels 100 forming the pixel column PG so as to extend over the pixels 100 arranged in the X direction. For example, in the Y direction, the green filter layer 122 is provided between the red filter layer 121 and the blue filter layer 123.

The interconnect 50 is provided in the insulating layer 91. The interconnect 50 is provided in a layer between the color filter 120 and the surface of the semiconductor substrate 90. The interconnect 50 is used as, for example, a signal line of the pixel array 10 or a power supply line of the pixel array 10. The interconnect 50 functions as a light shielding film for preventing the crosstalk of light between the pixels 100 adjacent to each other. The interconnect 50 is a metal layer including copper (Cu) or aluminum (Al). Note that the interconnect 50 may be a conductive layer in an electrically floating state.

The interconnect 50 has a plurality of openings OP. The opening OP has a quadrangular shape as viewed from the Z direction. The opening OP overlaps the pixel 100 in the Z direction.

The interconnect 50 includes an interconnect portion 501 extending in the X direction and an interconnect portion 502 extending in the Y direction. The interconnect portion 501 is continuous with the interconnect portion 502. The interconnect portions 501 are arranged in the Y direction. The interconnect portions 502 are arranged in the X direction. The interconnect portion 501 is provided in a region between the two openings OP arranged in the Y direction as viewed from the Z direction. The interconnect portion 502 is provided in a region between the two openings OP arranged in the X direction as viewed from the Z direction. The interconnect portion 502 covers the end portion of the pixel 100 in the X direction in the Z direction. The interconnect portion 501 and the interconnect portion 502 surround the opening OP. The interconnect portion 501 may cover the end portion of the pixel 100 in the Y direction in the Z direction.

A dimension (an interval between the interconnect portions 501 arranged in the Y direction) Dy of the opening OP along the Y direction is equal to or less than the dimension Py of the pixel 100 along the Y direction. However, the dimension Dy may be greater than the dimension Py depending on the specification or design of the linear image sensor. A dimension (an interval between the interconnect portions 502 arranged in the X direction) Dx of the opening OP along the X direction is less than the dimension Px of the pixel 100 along the X direction. The dimension Dx is less than the dimension Dy of the pixel 100 along the Y direction.

The light condensing of the pixel 100 in the Y direction is secured according to the dimension Dy of the opening OP. The light condensing of the pixel 100 in the X direction is secured according to the size (for example, the lens width of the microlens ML) of a region where the microlens ML condenses light.

The area of the pixel 100 that can receive light depends on the dimension of the opening OP. For example, in a case where the dimension Dy is equal to or less than the dimension Py, the area of the pixel 100 that can receive light is set as about “Dy×Dx”.

The microlens array 150 is provided on the color filter 120 in the Z direction. The microlens array 150 includes a plurality of microlenses ML. The microlens ML has a semi-cylindrical (or semi-elliptic cylindrical) structure.

Each microlens ML is provided on a corresponding one filter layer of the filter layers 121, 122, 123. One microlens ML overlaps one pixel 100 in the Z direction.

In general, in a case where the length or width of the microlens increases with respect to the height of the microlens, the vicinity of the end portion of the microlens becomes a spherical surface according to the material of the microlens or the processing condition of the microlens. However, the surface of the microlens becomes flat in the center portion of the microlens further away from the end portion.

The microlens ML has a semicircular or semi-elliptical cross-sectional shape (dome-like cross-sectional shape) as viewed from the Y direction. The microlens ML has a curvature from the upper end toward the end portion (side portion) in the X direction in the cross-sectional shape viewed from the Y direction.

Note that the cross-sectional shape of the microlens ML viewed from the Y direction is not limited to a semicircle or a semi-ellipse as long as the cross-sectional shape of the microlens ML viewed from the Y direction is a shape having a predetermined curvature around the axis (dome-like shape).

The end portion in the X direction of the microlens ML has a curved (spherical) structure. The curved surface shape of the end portion of the microlens ML in the X direction is designed such that light is refracted toward the opening OP. As a result, light from the X direction is incident on the pixel 100 by the lens effect of the microlens ML. Therefore, the curved surface shape of the end portion of the microlens ML in the X direction contributes to the condensing of light from the X direction by the lens effect.

At the boundary between the microlenses ML adjacent to each other in the X direction, curved surfaces contributing to light condensing are adjacent to each other, and the curved surfaces are continuous.

The microlens ML has a quadrangular cross-sectional shape as viewed from the X direction. The microlens ML includes a flat upper end (upper surface) in a cross-sectional shape viewed from the X direction.

The end portion (hereinafter, also referred to as a curved surface portion) 111 of the microlens ML in the Y direction has, for example, a curved structure. The curved surface portion 111 is provided at a position away from the opening OP. The curved surface portion 111 is separated from the end portion of the pixel 100 by a distance that does not contribute to the condensing of light. The interconnect 50 is interposed on a straight line connecting the curved surface portion 111 and the pixel 100. Even if the light is refracted by the curved surface shape of the end portion 111 of the microlens ML in the Y direction, the incidence of the light on the pixel 100 is blocked by the interconnect portion 501. Therefore, the curved surface shape of the end portion 111 of the microlens ML in the Y direction does not contribute to the condensing of light from the Y direction. As a result, the light from the Y direction is incident on the pixel 100 without being affected by the lens effect.

Since the semi-cylindrical microlenses ML do not contribute to the condensing of the light from the Y direction by the lens effect, the curved surfaces of the microlenses ML arranged to each other in the Y direction may not be adjacent to each other.

For example, a region not covered by the microlenses ML (hereinafter, a non-light condensing region) 99 is generated in a region between the microlenses ML adjacent to each other in an oblique direction. The non-light condensing region 99 is disposed above a portion that does not contribute to the detection of light of the pixel 100.

As described above, in a state where the light condensing effect of the microlens ML is not included, the dimension of a region through which light passes from the microlens ML toward the pixel 100 along the Y direction (dimension affecting the detection of light) is defined based on the interval Dy between the interconnect portions 501 (dimension Py of the pixel 100 along the Y direction), and the dimension of the region through which light passes from the microlens ML toward the pixel 100 along the X direction is defined based on the interval Dx between the interconnect portions 502.

Therefore, the light from the X direction is condensed by the X-direction side portion having the spherical shape of the microlens ML by the semi-cylindrical microlens ML. As a result, the amount of light from the X direction is secured.

The solid-state imaging device 1 according to the present embodiment includes a semi-cylindrical (or semi-elliptic cylindrical) microlens ML. As a result, the solid-state imaging device 1 according to the present embodiment can suppress a decrease in the sensitivity of the pixel in the pixel array 10.

### Conclusion

Image reading devices, such as copiers or scanners, include solid-state imaging devices for reading data, such as images. Although the speed of the image reading device has been increased year by year, the accumulation time of incident light tends to decrease due to the increase in speed. From the viewpoint of cost and development efficiency, in a case where the same light source as the existing device is used, the output level of the light incident on the pixel decreases due to the decrease in the accumulation time of the incident light. For this reason, there is a possibility that the image quality of the acquired image is deteriorated.

Therefore, the solid-state imaging device is required to have high speed and high sensitivity.

In a general solid-state imaging device, in a case where an island type microlens is used in a microlens array, a non-light condensing region occurs at a boundary between microlenses that cannot be covered by the microlens. Therefore, in the general solid-state imaging device, the condensing rate of the incident light decreases, and the sensitivity of the pixel decreases.

The solid-state imaging device 1 according to the present embodiment includes the microlens ML having the semi-cylindrical (or semi-elliptic cylindrical) structure. The semi-cylindrical microlens ML includes the curved surface (lens-shaped curved surface) having a lens effect at the end portion in the X direction.

In the present embodiment, the dimension of the region through which light passes with respect to the pixel 100 along the Y direction corresponds to the dimension Dy (alternatively, the dimension Py of the pixel 100 along the Y direction) between the interconnect portions 501, and a dimension of a region through which light passes with respect to the pixel 100 along the X direction corresponds to the dimension Dx between the interconnect portions 502 arranged in the X direction. The dimension Dx is less than the dimension Px.

Therefore, in the present embodiment, the microlens ML can improve the condensing of light from the X direction in which the size of the effective region of the pixel 100 is small.

In a case where the semi-cylindrical microlenses ML are disposed in an array in the pixel array 10 as in the present embodiment, the non-light condensing region 99 that affects the sensitivity of the pixel can be reduced.

For example, the solid-state imaging device 1 according to the present embodiment can improve the sensitivity of the pixel 100 by about 5% as compared with a general solid-state imaging device. As the size of the pixel is reduced, the effect of the solid-state imaging device 1 according to the present embodiment increases.

In the present embodiment, the microlens ML has the semi-cylindrical structure extending in the Y direction, and therefore the influence of misalignment between the microlens ML and the opening OP in the Y direction can be reduced. Therefore, the solid-state imaging device 1 according to the present embodiment can improve a manufacturing yield and throughput.

As described above, the solid-state imaging device 1 according to the present embodiment can receive the light from the Y direction (the row direction of the pixel array 10) in the region corresponding to the pixel 100 via the opening OP, and can condense the light from the X direction (the column direction of the pixel array 10) whose size is limited by the interconnect 50 using the lens effect of the microlens ML.

As a result, the solid-state imaging device 1 according to the present embodiment can improve the sensitivity of the pixel without deteriorating the resolution in the column direction.

Therefore, the solid-state imaging device 1 according to the present embodiment can improve the characteristics of the solid-state imaging device.

### (2) Second Embodiment

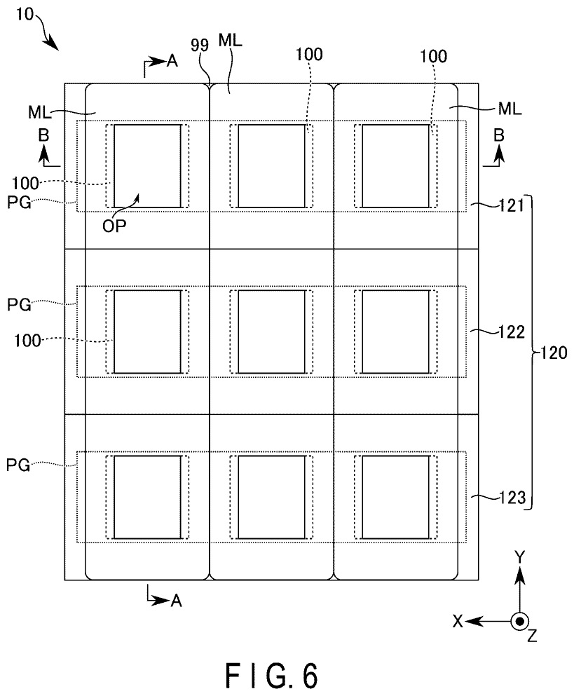

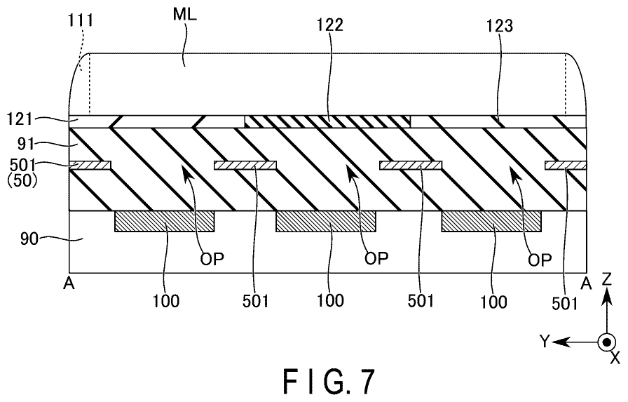

A solid-state imaging device according to a second embodiment will be described with reference to FIGS. 6 to 7.

FIG. 6 is a plan view illustrating the structure example of a pixel array 10 in a solid-state imaging device 1 according to the present embodiment. FIG. 7 is a cross-sectional view illustrating the structure example of the pixel array 10 in the solid-state imaging device 1 according to the present embodiment. FIG. 7 illustrates the cross-sectional structure of the pixel array 10 along line A-A in FIG. 6. Note that the cross-sectional structure of the pixel array 10 taken along line B-B in FIG. 6 is substantially the same as the structure illustrated in FIG. 5.

As illustrated in FIGS. 6 and 7, one semi-cylindrical (semi-elliptical cylindrical) microlens ML may be provided above a plurality of pixels 100 arranged in a Y direction. The microlens ML extends in the Y direction from one end to the other end of the pixel array 10. One microlens ML extends over a plurality of pixel columns PG arranged in the Y direction.

One microlens ML is provided on a color filter 120 so as to extend over a red filter layer 121, a green filter layer 122, and a blue filter layer 123. Therefore, the microlens ML overlaps the pixels 100 corresponding to different wavelength bands in a Z direction.

One microlens ML extends in the Y direction at the boundary between the pixels 100 arranged in the Y direction. The end portion of the lens shape of the microlens ML in the Y direction is not provided in a region between the pixels 100 arranged in the Y direction.

As a result, a non-light condensing region 99 is not generated in a region above the pixels 100 arranged in an array.

Therefore, in the present embodiment, the adverse effect caused by the light condensing of the microlens ML from the Y direction on each pixel 100 can be suppressed.

As described above, the solid-state imaging device 1 according to the present embodiment can improve the characteristics of the solid-state imaging device.

### (3) Third Embodiment

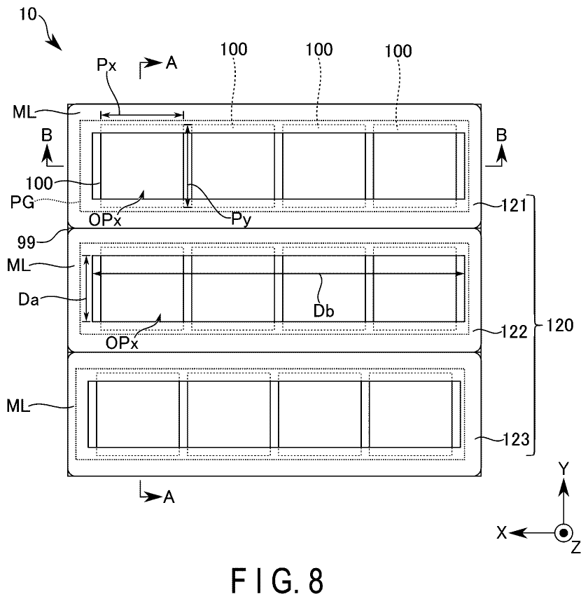

A solid-state imaging device according to a third embodiment will be described with reference to FIGS. 8 to 10.

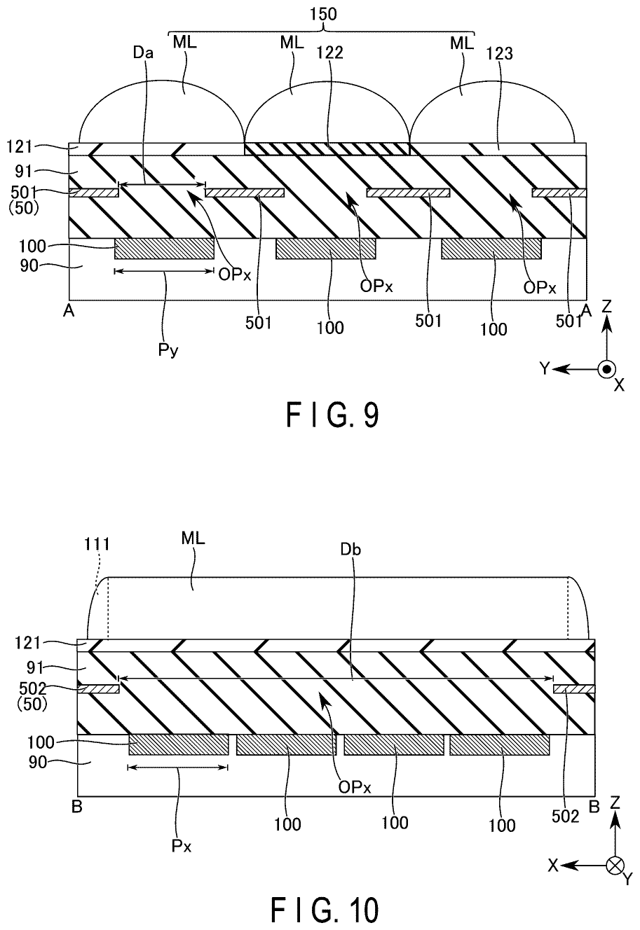

FIG. 8 is a plan view illustrating the structure example of a pixel array 10 in a solid-state imaging device 1 according to the present embodiment. FIGS. 9 and 10 are cross-sectional views illustrating the structure examples of the pixel array 10 in the solid-state imaging device 1 according to the present embodiment. FIG. 9 illustrates the cross-sectional structure of the pixel array 10 along line A-A in FIG. 8. FIG. 10 illustrates the cross-sectional structure of the pixel array 10 along line B-B in FIG. 8.

As illustrated in FIGS. 8 to 10, in the microlens array 150, each microlens ML may have a semi-cylindrical or semi-elliptic cylindrical structure extending in an X direction.

Each microlens ML extends in the X direction. Each microlens ML extends over a plurality of pixels 100 arranged in the X direction. Each microlens ML is provided on each filter layer 121, 122, 123 corresponding to one wavelength band (color). Therefore, the microlens ML overlaps a pixel column PG including a plurality of pixels 100 corresponding to one wavelength band in a Z direction. For example, a certain microlens ML overlaps the pixel column PG below the red filter layer 121 in the Z direction. Another microlens ML overlaps the pixel column PG below the green filter layer 122 in the Z direction. Another microlens ML overlaps the pixel column PG below the blue filter layer 123 in the Z direction.

The microlenses ML are adjacent to each other in a Y direction.

In a case where the microlens ML extends in the X direction, an opening OPx is provided in an interconnect 50 so as to extend over the pixels 100 arranged in the X direction. The opening OPx extends in the X direction. An interconnect portion 502 is not provided in a region between the pixels 100 arranged in the X direction. The pixels 100 arranged in the X direction is not optically separated. In the X direction, the opening OPx has a dimension Db. The dimension Db is equal to or greater than the sum (here, 4×Px) of the dimensions Px in the X direction of the pixels arranged in the X direction.

In the Y direction, the opening OPx has a dimension Da. The dimension Da is less than the dimension Py of the pixel 100.

The microlens ML has a semicircular or semi-elliptical cross-sectional shape (dome-like shape) as viewed from the X direction. The curved surface having the lens effect of the microlens ML is provided at the end portion on the Y direction side of the microlens ML. The curved surfaces face each other between the microlenses ML adjacent to each other in the Y direction.

The microlens ML has a quadrangular cross-sectional shape as viewed from the Y direction. The microlens ML includes a flat upper surface as viewed from the Y direction. In a case where the microlens ML extends in the X direction, a curved surface portion 111 is provided at an end portion of the microlens ML in the X direction. The curved surface portion 111 is provided at a position overlapping an interconnect portion 501 in the Z direction so as not to contribute to light condensing.

As described above, in the solid-state imaging device 1 according to the present embodiment, the semi-cylindrical (or semi-elliptic cylindrical) microlens ML is provided so as to extend over the pixels 100 (pixel column PG) that detect light of the same wavelength band. Also in this case, the solid-state imaging device 1 according to the present embodiment can obtain substantially the same effects as those of the solid-state imaging devices according to the other embodiments described above.

Therefore, the solid-state imaging device 1 according to the present embodiment can improve the characteristics of the solid-state imaging device.

### (4) Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a plurality of pixels provided on a substrate and arranged in a first direction and a second direction that are parallel to a surface of the substrate and intersect with each other; and
a plurality of microlenses provided above the substrate, wherein
each of the plurality of microlenses has a semi-cylindrical or semi-elliptic cylindrical structure extending in the first direction.

2. The solid-state imaging device according to claim 1, wherein
each of the plurality of microlenses includes a curved surface in the second direction.

3. The solid-state imaging device according to claim 1, further comprising:
an interconnect provided between the plurality of pixels and the plurality of microlenses in a third direction perpendicular to the surface of the substrate and having a plurality of openings, wherein
a first opening of the openings overlaps a first pixel of the plurality of pixels in the third direction,
a dimension of the first opening along the first direction is equal to or less than a dimension of the pixel along the first direction, and
a dimension of the first opening along the second direction is less than a dimension of the pixel along the second direction.

4. The solid-state imaging device according to claim 3, wherein
each of the plurality of microlenses includes a first end having a curved surface in the first direction, and
the first end overlaps the interconnect in the third direction and is separated from ends of the plurality of pixels.

5. The solid-state imaging device according to claim 1, wherein
each of the plurality of microlenses is arranged in the second direction,
the plurality of microlenses include a first microlens and a second microlens adjacent to each other in the second direction, and
a curved surface of the first microlens faces a curved surface of the second microlens in the second direction.

6. The solid-state imaging device according to claim 1, wherein
each of the plurality of microlenses is arranged in the first direction and the second direction, and
each of the plurality of microlenses overlaps each of the plurality of pixels in a third direction perpendicular to the surface of the substrate.

7. The solid-state imaging device according to claim 6, further comprising
a color filter provided between the plurality of microlenses and the plurality of pixels in the third direction perpendicular to the surface of the substrate and including a first filter corresponding to a first wavelength band, a second filter corresponding to a second wavelength band, and a third filter corresponding to a third wavelength band, wherein
the first filter, the second filter, and the third filter extend in the second direction,
the first filter, the second filter, and the third filter are arranged in the first direction,
each of first microlenses arranged in the second direction among the plurality of microlenses is provided above each of first pixels arranged in the second direction among the plurality of pixels with the first filter interposed therebetween,
each of second microlenses arranged in the second direction among the plurality of microlenses is provided above each of second pixels arranged in the second direction among the plurality of pixels with the second filter interposed therebetween, and
each of third microlenses arranged in the second direction among the plurality of microlenses is provided above each of third pixels arranged in the second direction among the plurality of pixels with the third filter interposed therebetween.

8. The solid-state imaging device according to claim 1, wherein
each of the plurality of microlenses overlaps first pixels arranged in the first direction among the plurality of pixels in a third direction perpendicular to the surface of the substrate.

9. The solid-state imaging device according to claim 1, further comprising
a color filter provided between the plurality of microlenses and the plurality of pixels in a third direction perpendicular to the surface of the substrate and including a first filter corresponding to a first wavelength band, a second filter corresponding to a second wavelength band, and a third filter corresponding to a third wavelength band, wherein
the first filter, the second filter, and the third filter extend in the second direction,
the first filter, the second filter, and the third filter are arranged in the first direction, and
a first microlens among the plurality of microlenses is provided above first pixels arranged in the first direction among the plurality of pixels with the first filter, the second filter, and the third the filter interposed therebetween.

10. The solid-state imaging device according to claim 1, further comprising
a color filter provided between the plurality of microlenses and the plurality of pixels in a third direction perpendicular to the surface of the substrate and including a first filter corresponding to a first wavelength band, a second filter corresponding to a second wavelength band, and a third filter corresponding to a third wavelength band, wherein
the first filter, the second filter, and the third filter extend in the first direction,
the first filter, the second filter, and the third filter are arranged in the second direction, and
a first microlens among the plurality of microlenses is provided above first pixels arranged in the first direction among the plurality of pixels with the first filter interposed therebetween.

11. The solid-state imaging device according to claim 10, further comprising:
an interconnect provided between the plurality of pixels and the color filter in the third direction and having a plurality of openings, wherein
a first opening among the openings extends in the first direction, and
the first opening is provided above the first pixels in the third direction.

12. The solid-state imaging device according to claim 11, wherein
a dimension of the first opening along the first direction is equal to or greater than a sum of dimensions of the first pixels along the first direction.

13. The solid-state imaging device according to claim 1, wherein
each of the plurality of microlenses includes a flat upper end as viewed from the second direction.

14. The solid-state imaging device according to claim 1, wherein
each of the plurality of microlenses has a quadrilateral structure as viewed from the second direction.

15. The solid-state imaging device according to claim 1, wherein
a first end of each of the plurality of microlenses in the first direction has a curved structure.

16. The solid-state imaging device according to claim 1, wherein
each of the plurality of microlenses has a dome-like structure as viewed from the first direction.
